(19) United States
(12) Patent Application Publication
(10) Pub. No.: US 2019/0211446 A1
(43) Pub. Date: Jul. 11, 2019

(54) A Non-Contact Substrate Carrier for Simultaneous Rotation and Levitation of a Substrate

(71) Applicant: Singulus Technologies AG, Kahl am Main (DE)

(72) Inventors: Alexey IVANOV, Aachen (DE); Andreas KLEPL, Aschaffenburg (DE); Johannes RICHTER, Dieburg (DE)

(73) Assignee: Singulus Technologies AG, Kahl am Main (DE)

(21) Appl. No.: 16/323,962

(22) PCT Filed: Jun. 27, 2017
(86) PCT No.: PCT/EP2017/065830

§ 371 Date: Feb. 7, 2019

(30) Foreign Application Priority Data
Aug. 9, 2016 (EP) 16183400.7

(51) Int. Cl. C23C 16/458; C23C 16/455; C23C 16/46; C23C 16/52; H01J 37/32

(52) U.S. Cl. CPC C23C 16/4584; C23C 16/45565; C23C 16/4557; C23C 16/45574; H01J 37/32724; C23C 16/52; H01J 37/32449; H01J 37/32522; C23C 16/46

(57) ABSTRACT

A system and a corresponding method for simultaneous rotation and levitation of a substrate during deposition and/or etching of the substrate are disclosed. The system comprises a carrier located below the substrate, wherein the carrier comprises at least two gas inlets to provide gas to a bottom surface of the substrate to levitate the substrate above the carrier. The system further comprises at least one holding member connected to the carrier and being configured to restrict horizontal drifting of the substrate.

The present invention relates to non-contact substrate carriers and methods thereof In particular, the present invention relates to substrate carriers and methods for simultaneous rotation and levitation of a substrate during deposition and/or etching of the substrate.

The placement of substrates should satisfy certain requirements, e.g. homogeneous temperature distribution, steady deposition and/or removal of material and/or process gas guidance, in any kind of deposition, etching or other thermal process. In general tool configurations depend among other things on the quantity of substrates that are to be processed at the same time. Depending on the specific application, the size of substrates and/or the amount of substrates to be processed at the same time, there are different options for holding the substrates. In particular, there is a variety of tool configurations which may be divided into the following groups in regard to number of parallel processed substrates: a single substrate system, a small/mini-batch system (<10 substrates) or a multi-batch system (up to 100 substrates and more). The system or chamber capacity depends on the process type and the substrate temperature. Some processes are suitable for multi-batch configurations, e.g. processes with low process temperature and/or processes with naturally uniform deposition or etching, therefore lowest process costs per substrate may be achieved. On the contrary, some other processes are less suitable for multi-batch configurations, e.g. because of very high process temperatures and/or complex processes to achieve a uniform deposition or etching. Mini-batch systems are usually used for small substrates, where process costs can be reduced by filling an area with a number of small substrates resembling a single large substrate and thus remaining single substrate system compatibility.

The tool configuration also depends on the size of the substrate(s) to be processed. For example, certain aspects that are rather simple with respect to small substrates, may become problematic for large substrates. That is, from a tool configuration point of view, it may be easier to place multiple (10+) small (for example 50,8 mm) substrates on a single carrier instead of 300 mm substrates which are widely used in the semiconductor industry. In other words, the amount of substrates to be processed at the same time is not restricted by the size of the carrier/reactor for small substrates, i.e. several substrates may be placed onto a single carrier. For increasing substrate sizes, the size of the carrier/reactor may be limiting for the amount of substrates which may be placed onto a single substrate carrier, i.e. onto a single plane of a substrate carrier. Thus, usually the substrates with a diameter of 150 mm and larger are placed into vertical stacks for multi-batch systems. For small batch and single substrate systems, the substrates are rather placed into pockets/recesses of large carriers or in single holders.

In prior art systems, a single substrate holder consists of a main body with a recess, which is usually adapted to the geometry of the substrate and might have a flat, concave, convex or any other complex profile of its bottom surface facing the substrate.

FIG. 1 shows a partial view of such an assembly of substrate and carrier 10 according to the prior art. In particular, FIG. 1 shows a carrier 11 having a recess and a holding member 12, wherein the substrate 13 is placed within the recess of the carrier 11 and on top of the holding member 12.

In addition, FIG. 1 shows the radial temperature variation 15 along the assembly 10. The complex temperature profile is due to the complex setup (materials, gaps, geometries, etc.). Thus, the temperature variation causes turbulences near the substrate's edge and parasitic mass transfer from previous coatings 14, which are residues deposited on the surrounding parts of the system, e.g. the holder, in a previous process, to the substrate's surface due to the negative temperature gradient towards the substrate 13. The substrate 13 may be a free standing object and can move off-axis within the recess, i.e. with respect to a central axis A of the assembly 10, and therefore deteriorate the temperature uniformity at its edge. That is, the substrate may move within the recess, which may have a negative influence on the homogeneous temperature distribution, steady deposition and/or removal of material, composition of the deposited materials etc.

Furthermore, at high temperatures and low pressures the gap between parts (e.g. substrate and carrier) is more important for heat transfer/temperature difference than the thermal conductivity of any particular material. Considering a sandwich structure, wherein the main body is placed on top of a heater and the substrate is carried by the main body, the substrate temperature will always be lower than the temperature of the main body and the surrounding parts.

The recess depth is usually comparable with the thickness of the substrate 13 and in most cases slightly larger. The main reason for such a design is to ensure a stable substrate position over the whole process time and to prevent the reactants from going underneath the substrate and perform coating or etching on its backside.

During the process the substrate 13 might obtain a concave or convex shape due to stress caused by the temperature or by modifications of the substrate's surface, due to a deposition and/or etching process. These effects usually prevent a further reduction of the recess depth. A complex surface shape of the carrier 11 is an additional reason for an increased barrier height and even lower substrate temperatures (larger gap). Not considering these effects in the substrate carrier design may cause the substrate to move uncontrollably during the process or causing parasitic modification (coating or etching) of its backside.

At the same time the surrounding barrier disturbs the flow of the process gas, so that in most cases the substrate may develop a highly non-uniform deposition or etching profile within its edge area. In the case of ternary or higher level (quaternary etc.) compounds growth, the composition non-uniformity may reach values that are not acceptable for further utilization.

In order to obtain a better temperature uniformity (and other possible benefits), it is known in the art to utilize substrate rotation. However, the outer barriers in these systems cause high flow disturbances and thus lead to even higher degradation of the edge area.

US 2008/0280453 A1 discloses an apparatus and system that are used to support, position, and rotate a substrate during processing.

US 2010/0200545 A1 discloses a method for processing a substrate. The method comprises positioning the substrate on a substrate receiving surface of a susceptor, and rotating the susceptor and the substrate by delivering flow of fluid from one or more rotating ports.

U.S. Pat. No. 5,983,906 A relates to the provision of a flow restrictor ring and other features that allow a 15 liters/minute flow rate through the chamber with minimal backside deposition and minimized deposition on the bottom of the chamber, thereby reducing the frequency of chamber cleanings, and reducing clean time and seasoning.

U.S. Pat. No. 6,183,565 B1 relates to a method for contactless treatment of a substrate such as a semiconductor wafer, comprising enclosing the wafer in an apparatus and applying two gas streams, in opposing directions, from first and second side sections located opposite one another, to the two opposing planar sides or surfaces of the wafers.

However, the solution proposed by U.S. Pat. No. 6,183,565 B1 is applicable for single substrate systems at low temperature processes (T<500 C) and static substrate positioning (no rotation or movement of the substrate). In such a case there is less risk for the substrate to move uncontrollably (e.g. to fly-away) and there is no need for rotation to at least improve the substrate temperature uniformity. The radiation component of the heat transfer is negligible; therefore the temperature difference between the carrier and substrate is insignificant.

In addition, U.S. Pat. No. 5,226,383 A relates to a foil susceptor for rotating a wafer, wherein spiral channels at the bottom of a disk which bears the wafer achieve the rotation of the wafer. However, the additional use of a profiled intermediate holder has negative impact on the temperature profile across the wafer, in particular for high-temperature processes (>500° C.).

The contactless treatment of a substrate has several advantages regarding the temperature distribution and the ramping time, but suffers from incompatibility with large scale deposition and/or etching processes, due to the unstable substrate position in case the process gap is larger than 2 mm. Furthermore, the systems require about 1500 slm gas flow for the substrate levitation, whereas common processes use 1 to 10 slm process gas flow for deposition and/or etching. This difference has a direct impact on the main process. To overcome this issue one would need to increase the process gas flow to comparable values. In addition, working at low pressure would require using a very powerful vacuum pump or a number of pumps. In addition, these systems require recesses on both sides of the substrate, and thus creating all problems connected to these recesses as outlined above.

Usually an edge exclusion parameter, i.e. an area at the edge of the substrate which may be unusable after processing of the substrate reaching in some cases up to 5 mm, is defined. Thus, in case of 150 mm substrates the lost area is about 13%, for 200 mm it's about 10% and for 300 mm almost 7%. Despite the percentage drop for larger diameter the absolute lost area size is increasing more than twice between 150 mm and 300 mm, and for 150 mm has the size of a square area with 48 mm side length.

The object of the invention is to provide a system and method using a non-contact substrate carrier, which overcome at least some of the above-mentioned problems of the prior art. In particular, one object of the present invention is to overcome the various negative impacts of the recess(es).

As outlined above the utilization of recess(es) may have a negative influence on the substrate's temperature distribution due to the proximity and/or different proximities (off-axis) of the substrate to the recess edge. In addition, the recess(es) may influence the gas flow pattern due to the strong local temperature non-uniformity between the substrate, carrier edge and the outer parts. Furthermore, the recess(es) may influence the gas flow pattern due to the geometry of the carrier edge in combination with carrier rotation and results in worse thickness and/or composition uniformity of deposition, or etching processes. In addition, the recess(es) may influence subsequently grown layers and their thickness and/or composition uniformity.

Also, the present invention overcomes the requirement to replace substrate carriers before each process to prevent substrate contamination coming from residual depositions on carrier and reactor parts during previous process. Furthermore, the present invention may overcome the requirement of a baking (annealing) process before each process to avoid outgassing from replaced parts, wherein the additional process would increase production cycle time, decrease throughput and increase products costs.

The present invention further minimizes the possibility to create particles on the substrate's surface due to flow turbulences and temperature distributions (local cold spot areas).

In addition, the present invention may overcome the problem of self-promoted substrate bowing effects due to local physical contact of the substrate to the substrate holder.

Additionally, the present invention overcomes the incompatibility of a standard carrier with full automation wafer handling in production mode (FOUP to FOUP/Cassette to Cassette), which is due to the necessity to separate the substrate from the carrier. Normally, an additional handling device is needed to separate the wafer and the carrier, this requires additional space, time and creates handling problems. This has a negative economic impact (cost of ownership, etc.).

The objects are achieved with the features of the independent claims. The dependent claims relate to further aspects of the invention.

The invention is based on the general inventive idea to provide a substrate carrier with gas inlets to provide a rotational force to the substrate as well as a levitation effect to the substrate for improved material deposition and/or etching.

In one aspect of the present invention a system for simultaneous rotation and levitation of a substrate during deposition and/or etching of the substrate is provided. The substrate has a bottom surface and a top surface. The system comprises a heater. The heater comprises a carrier located below the substrate, wherein the carrier comprises at least three gas inlets to provide gas to the substrate's bottom surface to levitate the substrate above the carrier and to simultaneously rotate the substrate. The system further comprises at least one holding member connected to the carrier and being configured to restrict horizontal drifting of the substrate. The heater is configured to apply heat to the bottom surface of the substrate and to the top surface of the substrate.

That is, the substrate may be placed symmetrically onto the holding member, wherein the at least one holding member avoids horizontal drifting of the substrate. In addition, the levitation effect leads to a substrate which is not in contact with the carrier. Thus, a more stable temperature profile across the substrate may be achieved. While the holding member may engage the substrate, the holding member may be positioned and/or sized in such a manner that the adverse effects on temperature profile and growth are confined to a small fraction of the substrate area.

The substrate carrier according to the present invention is part of heater system. The heater system may be the system according to European Patent Application 15 20 2296.8.

The gas inlets are preferably inclined with respect to a vector normal to the substrate's radius, wherein the inclined gas inlets lie within a plane which is parallel to a tangential plane to the substrate's edge to provide a rotational force to the substrate.

That is, the gas inlets are preferably tilted or inclined clockwise or counter-clockwise to provide a rotational force to the substrate and at the same time provide an upward force to the substrate to lift the substrate up, i.e. to levitate the substrate above the carrier of the substrate carrier.

The inclined gas inlets may lie within a plane defined by (i) a first vector which is normal to the substrate's radius or the carrier's radius and (ii) a second vector which lies within the bottom plane of the substrate or carrier and which is perpendicular to the substrate's radius or the carrier's radius at the position of the inclined gas inlet. The inclined gas inlets may be inclined with respect to a vector which is normal to the radius vector of the substrate or carrier and which lies within a plane of the bottom surface of the substrate or carrier.

An inclination angle of the inclined gas inlets, measured as angle between a center line of the gas inlet and the vector normal to the bottom surface of the substrate, may be between 2° and 60°, preferably between 5° and 50°, more preferably between 10° and 45°. In some embodiments, the inclination angle may be between 25° and 35°. In some embodiments, the inclination angle may be between 28° and 32°.

The gas is thus applied to the bottom surface of the substrate and therefore prevents process gas applied to the top surface of the substrate from going under the substrate and produce parasitic coating or etching on the bottom surface of the substrate.

In addition, due to the flow over rotating disc effect, the rotating substrate will attract the process gas closer to the substrate and the carrier and thereby improve the efficiency of the deposition or etching process.

The at least one holding member may comprise a single holding member located at the carrier such that the substrate is positioned at a center position of the carrier.

Alternatively or additionally, the at least one holding member comprises at least three holding members located at the carrier such that the three holding members receive the substrate at an edge region thereof.

That is, the central holding member may be provided in addition to the at least three holding members provided at the edge region of the substrate.

The central holding member and/or the at least three holding members at the substrates edge region may be pins. The pin may have a diameter that increases towards the carrier.

The holding member(s) may be adapted to engage, i.e., physically contact, the substrate to restrict or eliminate horizontal drifting thereof.

The at least three holding members at the substrates edge may be located such that they contact the substrate at its outside edge, i.e. the substrate may be surrounded by the at least three holding members, whereas the single holding member (central holding member) may penetrate through a predefined hole in the substrates center.

The at least one holding member may have an increasing diameter towards the carrier, wherein the diameter at the top of the carrier is larger than the diameter at the substrate/substrate's height.

The diameter of the at least one holding member may be increased towards the carrier gradually or using a step variation at a predetermined height above the carrier.

Thus, the substrate is prevented from coming into contact with the carrier even in its initial position, i.e. before applying the gas through the gas inlets. For illustration, the holding member(s) may be configured to engage the substrate so as to hold the substrate at a first distance from the carrier when no gas is applied through the gas inlets. Application of the gas through the gas inlets effects levitation of the substrate. The holding member(s) may still be adapted to engage the substrate when the substrate is levitated. The levitated substrate may be spaced from the holding member(s), with a boundary of the holding member(s) being offset from the levitated substrate so as to restrict horizontal drifting of the substrate.

The holding member(s) may be fixedly attached to the carrier. The holding member(s) may be attached to the carrier in a torque-prove manner. An attachment structure fixing the holding member(s) to the carrier may prevent the holding member(s) from rotating relative to the carrier.

The holding member(s) may be attached to the carrier so as to be rotatable relative to the carrier. The holding member(s) may be attached to the carrier via an attachment structure that may comprise a bearing rotatably supporting the holding member. The bearing may be a ball bearing, a roller bearing, or a gas bearing.

When one or more holding members that are rotatable relative to the carrier are used, a relative movement between the surface of the holding member and a surface of the substrate may be reduced or eliminated. The one or more holding members may be caused to rotate by rotation of the substrate. The one or more holding members may be rotationally driven. A rotation speed of the one or more holding members may be varied in dependence on a rotation speed of the substrate. For illustration, for one or more holding members that are respectively supported by a gas bearing, a rotation of the one or more holding members may be effected by a gas flow branched off from a supply line supplying the gas flow through the gas inlets in the carrier. A rotation speed of the holding member(s) may be set such that there is no or little slip between the surface of the holding member and the surface region of the substrate closest to the surface of the holding member.

The upper surface of the carrier facing the substrate may be substantially flat. The upper surface of the carrier may have a surface flatness of at most 0.1 mm. The upper surface of the carrier may have a surface flatness of at most 0.1 mm when determined using optical measurement techniques, such as optical measurement devices commercially available from k k-Space Associates, Inc., Dexter, Mich., USA. The upper surface of the carrier may have a surface flatness of at most 0.1 mm when determined in accordance with DIN ISO 2768. In the absence of a recess, the various advantageous as outlined above and summarized below are achieved.

The at least three inclined gas inlets may be formed as a hole or a hollow pin through the carrier. In other words, the carrier may be a solid material with holes provided therein or the carrier may be constructed as at least one hollow pin located underneath the substrate.

The at least three inclined gas inlets may be located such that gas is provided to a region below the substrate. The angle of inclination and the distance from the substrate's center may vary. However, to achieve the most efficient rotation (the highest rotation speed with lowest gas supply) the gas inlets may be placed as far as possible from the substrate's center and the inclination angle may be as far as possible from the normal direction in respect to the substrate plane. That is, the angle between the normal direction and the respective gas inlet may be at least 1° and higher, preferably at least 15° and higher, more preferably at least 25° and higher, even more preferably about 30°.

The at least one holding member may further comprise a rotational speed sensor and/or a positional sensor to measure the rotation and/or the position of the substrate, thereby, allowing to more accurately control the rotation and the position of the substrate based on the measured values.

Alternatively or additionally, the position of the substrate can be measured using optical techniques, in particular position measurement techniques using laser radiation. The rotation can also be measured optically, e.g. when the substrate has a notch.

A distance between the at least three gas inlets may be greater than 30% of a diameter of the substrate, preferably greater than 50% of the diameter of the substrate, more preferably greater than 70% of the diameter of the substrate.

A distance between the at least three gas inlets may be greater than 50 mm, preferably greater than 65 mm, more preferably greater than 80 mm.

The heater may comprise a first heating unit configured to heat the bottom surface of the substrate and a second heating unit configured to heat the top surface of the substrate. The first heating unit may be arranged below the bottom surface of the substrate. The second heating unit may be arranged above the top surface of the substrate. The first heating unit may comprise the carrier. The first heating unit may act as the carrier, i.e., the inclined gas inlets may be formed in the first heating unit.

The system may comprise a temperature control unit configured to control a first energy output of the first heating unit and a second energy output of the second heating unit independently of each other.

The system may be adapted to rotate the substrate with a rotational velocity between 60 rpm and 2000 rpm.

The system may be adapted to control the gas flow through the at least three gas inlets to control the rotational velocity of the substrate.

The system may comprise a gas injector configured to guide process gases to a substrate for gas phase deposition onto the substrate. The gas injector may comprise a first flow path and a second flow path different from the first flow path. The system may comprise a first gas temperature adjustment mechanism associated with the first flow path to control a temperature of process gases passing through the first flow path. The system may comprise a second gas temperature adjustment mechanism associated with at least the second flow path to control a temperature of process gases passing through the second flow path, the first gas temperature adjustment mechanism and the second gas temperature adjustment mechanism may be operable independently of each other.

The system may further comprise the second heating unit comprising the carrier, the second heating unit being configured to heat the bottom surface of the substrate.

According to another aspect of the present invention a method for simultaneous rotation and levitation of a substrate during deposition and/or etching of the substrate is provided. The substrate has a bottom surface and a top surface. The method comprises the steps of: (a) applying gas to the substrate's bottom surface facing a carrier through at least three gas inlets formed in the carrier to levitate the substrate above the carrier; (b) restricting horizontal drifting of the substrate by means of at least one holding member; and (c) heating the bottom surface and the top surface of the substrate during levitation and rotation.

The bottom surface of the substrate may be heated using a first heating unit which comprises the carrier.

Applying gas through the at least three gas inlets may comprise applying gas under a predetermined angle. The inclined gas inlets may lie within a plane defined by (i) a first vector which is normal to the substrate's radius or the carrier's radius and (ii) a second vector which lies within the bottom plane of the substrate or carrier and which is perpendicular to the substrate's radius or the carrier's radius at the position of the inclined gas inlet. The inclined gas inlets may be inclined with respect to a vector which is normal to the radius vector of the substrate or carrier and which lies within a plane of the bottom surface of the substrate or carrier.

An inclination angle between the gas inlets and a vector normal to the bottom surface of the substrate may be between 2° and 60°, preferably between 5° and 50°, more preferably between 10° and 45°. In some embodiments, the inclination angle may be between 25° and 35°. In some embodiments, the inclination angle may be between 28° and 32°.

Restricting horizontal drifting may comprise engaging a single holding member with the substrate at a single central position thereof.

Alternatively or additionally, restricting horizontal drifting may comprise confining an edge of the substrate with at least three holding members positioned at the edge of the substrate.

The method may further comprise holding the substrate at a predetermined first distance from the carrier before the application of the gas and at a predetermined second distance from the carrier after application of the gas, wherein the predetermined second distance is greater than the predetermined first distance. For illustration, the holding member(s) may be adapted to engage the substrate so as to hold the substrate at a first distance from the carrier when no gas is applied through the gas inlets. Application of the gas through the gas inlets effects levitation of the substrate. The holding member(s) may be adapted to still engage the substrate when the substrate is levitated. The levitated substrate may be spaced from the holding member(s), with a boundary of the holding member(s) being offset from the levitated substrate so as to restrict horizontal drifting.

Applying gas to the substrate's bottom surface may comprise applying gas through the at least three gas inlets, wherein a distance between each of the gas inlets and a center of the carrier may be greater than 30% of a radius of the substrate, preferably greater than 50% of the radius of the substrate, more preferably greater than 70% of the radius of the substrate.

For a 6″ wafer with a substrate radius of 75 mm, Applying gas to the substrate's bottom surface may comprise applying gas through the at least three gas inlets, wherein a distance between each of the at least three gas inlets and a center of the carrier may be greater than 22.5 mm, preferably greater than 37.5 mm, more preferably greater than 52.5 mm.

The method may further comprise measuring the rotation and/or the position of the substrate. The rotation and/or position of the substrate may be measured using the at least one holding member. The rotation and/or position of the substrate may be measured using a distance sensor or contact sensor provided on the holding member(s) and/or rotation speed sensors coupled to the holding member(s). Alternatively or additionally, the position of the substrate can be measured using optical techniques, in particular position measurement techniques using laser radiation. The rotation can also be measured optically, e.g. when the substrate has a notch.

The bottom surface and the top surface of the substrate may be heated independently from each other.

The substrate may be rotated with a rotational velocity between 60 rpm and 2000 rpm.

The method may further comprise the step of controlling the gas flow through the at least three gas inlets to control the rotational velocity of the substrate.

The method may comprise passing a first group of process gases through a first flow path of a gas injector to the substrate. The method may comprise passing a second group of process gases through a second flow path of the gas injector, the second flow path being different from the first flow path and the second group of process gases being different from the first process gases. The method may comprise controlling a first gas temperature adjustment mechanism associated with the first flow path to control a temperature of the first process gases passing through the first flow path. The method may comprise controlling a second gas temperature adjustment mechanism associated with at least the second flow path to control a temperature of the second group of process gases passing through the second flow path, the first gas temperature adjustment mechanism and the second gas temperature adjustment mechanism being operable independently of each other.

The gas injector may be positioned above the top surface of the substrate. The method may comprise controlling a heating unit positioned below the bottom surface of the substrate. The heating unit positioned below the bottom surface of the substrate may be controlled independently of the first and second gas temperature adjustment mechanisms. The first and second gas temperature adjustment mechanisms may both be integrated into or connected with a top heater. The heating unit positioned below the bottom surface of the substrate, which may be integrally formed with the carrier that has the gas inlets for levitating and rotating the substrates, must not be confused with the first and second gas temperature adjustment mechanisms.

The method may be performed using the system described above.

According to another aspect of the present invention the use of the above described substrate carrier or the method for vapor phase deposition, e.g. vapor phase epitaxy, is provided.

The present invention has several advantages. In particular, due to the absence of the recess the temperature variation at the substrate edge may be reduced or even avoided. Together with an active heater, the temperature profile may be adjusted according to the process requirements.

In addition, due to the absence of the recess the flow pattern disturbance near the substrate edge due to strong temperature variations may be avoided and the provision of a static carrier may avoid flow pattern disturbances near the substrate edge due to the rotation of the substrate. That is, according to the present invention no rotation of the carrier is necessary.

Furthermore, due to the absence of the recess, thickness non-uniformity of deposition or etching processes may be avoided and a composition non-uniformity of the deposition process may be avoided.

The absence of the recess further avoids the necessity of carrier replacement between subsequent runs and no separate baking and/or annealing processes are required, because the substrate is the only part undergoing the replacement between processes, and thus, increasing the reliability of the production process and its throughput.

Due to the flat design and the high speed substrate rotation parasitic particle generation may be reduced or even prevented. Due to the natural gap between the substrate and the carrier the influence of any substrate bow caused by the temperature profile may substantially be reduced or eliminated.

In addition, the present invention is fully compatible with full automation production mode (FOUP to FOUP/Cassette to Cassette). Thus, operation costs may significantly be reduced.

Also, because of the simplicity of the substrate carrier of the present invention which does not require moving parts or motors, and which does not require translation of rotation into the vacuum chamber, and the high speed rotation (e.g. up to 2000 rpm or even 3000 rpm) an improved precursor utilization above 50% may be realized, which has not been achieved by common deposition or etching systems.

Some preferred embodiments are now described with reference to the drawings. For explanation purpose, various specific details are set forth, without departing from the scope of the present invention as claimed.

### BRIEF DESCRIPTION OF DRAWINGS

FIG. 1 illustrates a part of a conventional substrate carrier system and its temperature distribution.

FIG. 2 is a sectional view of a first embodiment of a system according to an embodiment.

FIG. 3 is a sectional view of a second embodiment of a system according to an embodiment.

FIG. 4a is a perspective view of an arrangement of gas inlets of a system according to an embodiment.

FIG. 4b is a front view of an arrangement of gas inlets of a system according to an embodiment.

FIG. 5 illustrates the geometrical relations of the gas inlets with respect to the carrier according to the embodiments.

FIG. 6 is a top view of an embodiment of a system according to an embodiment.

FIG. 7 illustrates the lost area versus the exclusion width according to the prior art and embodiments of the present invention.

FIG. 8 is a schematic cross-sectional view of a system according to an embodiment.

FIG. 9 is a schematic cross-sectional view of a system according to an embodiment.

FIG. 10 is a schematic view of a system according to an embodiment.

FIG. 11 to FIG. 16 are views of a holding member of a system according to embodiments of the invention.

### DETAILED DESCRIPTION OF PREFERRED EMBODIMENTS

FIG. 2 illustrates a first exemplary embodiment of the present invention. FIG. 2 shows a system 100 comprising a substrate carrier 110, gas inlets 111, a holding member 120 and a substrate 130. The carrier 110 may be comprised by a heater. For illustration, the carrier 110 may be formed by a first heating unit adapted to heat the substrate 130 from a bottom side thereof. The system 100 may further comprise a second heating unit (not shown in FIG. 2) adapted to heat the substrate 110 from a top side thereof.

The carrier 110 has a substantially flat or specially profiled top surface. The carrier 110 according to the first embodiment has a holding member 120, which is located at a center position of the carrier 110.

The holding member 120 according to the first embodiment is a circular pin of a predetermined diameter so that the substrate 130 can be placed on top of, or otherwise in engagement with, the holding member 120. The holding member 120 receives the substrate 130 at a center position thereof by penetrating through a predefined hole in the substrate's center. The purpose of the holding member 120 is to hold the substrate in place while being rotated and levitated. That is, the holding member 120 restricts the horizontal movement of the substrate 130 during rotation and levitation.

As will be explained in more detail with reference to FIG. 11 to FIG. 16, the holding member 120 may have a cross-sectional area that increases towards the carrier 110. The holding member 120 may be formed by plural cylinders stacked on top of each other to form a stepped surface. The holding member 120 may be formed by a member having a conical or frustoconical outer surface. The holding member 120 may be rotationally symmetric. The holding member 120 may be attached to the carrier 110 so as to be non-rotatable relative to the carrier. Alternatively, the holding member 120 may be attached to the carrier 110 so as to be rotatable relative to the carrier 110, e.g., by means of a ball bearing, roller bearing, gas bearing, or other bearing.

At least three gas inlets 111 are located below the substrate at the carrier 110. The at least three gas inlets 111 may be located towards the edge of the substrate 130. When gas (levitation/rotation gas) is provided from below the substrate 130, the substrate 130 is elevated from its resting position. The substrate 130 may be disengaged from direct contact with the holding member 120 when it is levitated under the action of the gas flow, while the holding member 120 is still operative to restrict horizontal drifting of the substrate 130. For illustration, horizontal drifting of the substrate 130 may be limited by abutment of the holding member 120 on an inner circumference of a central hole formed in the substrate 130. The gas flow through the gas inlets 111 is illustrated by arrows below the substrate. The arrows above the substrate illustrate process gas of the deposition and/or etching process applied to the wafers top surface.

As will be explained in more detail below, the gas inlets 111 may be inclined to create a rotational force acting on the substrate 130. The gas flow passing through the gas inlets 111 may effect both a levitation and a rotation of the substrate 130.

FIG. 3 illustrates a second exemplary embodiment of the present invention. FIG. 3 shows a system 200 with a carrier 110, gas inlets 111, holding members 121 and a substrate 130. The carrier 110 may be comprised by a heater. For illustration, the carrier 110 may be formed by a first heating unit adapted to heat the substrate 130 from a bottom side thereof. The system 100 may further comprise a second heating unit (not shown in FIG. 2) adapted to heat the substrate 110 from a top side thereof.

Features corresponding to features already explained with reference to FIG. 2 are designated with the same reference numerals.

A difference between the first and the second embodiment is the arrangement of the holding members 121. The holding members 121 according to the second embodiment are placed at an edge region of the substrate 130. Although only two holding members 121 are visible in FIG. 3, three or more holding members 121 are provided. Thus, the substrate 130 according to the second embodiment is being held by three or more holding members 121 at an edge region of the substrate 130 and not at a center region of the substrate 130.

As will be explained in more detail with reference to FIG. 11 to FIG. 16, the holding members 121 may have a cross-sectional area that increases towards the carrier 110. The holding members 121 may be formed by plural cylinders stacked on top of each other to form a stepped surface. The holding member 120 may be formed by a member having a conical or frustoconical outer surface. The holding members 121 may be rotationally symmetric. The holding members 121 may be attached to the carrier 110 so as to be non-rotatable relative to the carrier 110. Alternatively, the holding members 121 may be attached to the carrier 110 so as to be rotatable relative to the carrier 110, e.g., by means of a ball bearing, roller bearing, gas bearing, or other bearing.

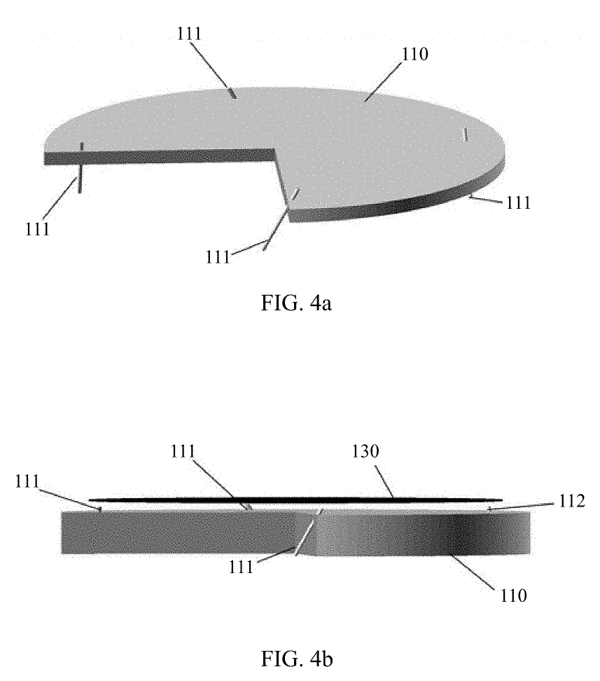

FIGS. 4a and 4b illustrate a third exemplary embodiment of the present invention. FIG. 4a is a perspective view and FIG. 4b is a front view of the third exemplary embodiment. With respect to the features of the first and second embodiment which are also present in the third embodiment reference is made to the respective description. In particular, the third exemplary embodiment may employ any of the above mentioned holding members 120 and/or 121 (not shown in FIG. 4a and FIG. 4b).

FIG. 4a shows four gas inlets 111 and the carrier 110. FIG. 4b shows four gas inlets 111, the carrier 110 and the substrate 130. The arrangement of gas inlets 111 illustrated in FIG. 4a and FIG. 4b may be provided in a first heating unit that acts as a carrier and is operative to provide energy to the substrate 130 from a bottom side thereof The carrier 110 illustrated in FIG. 4a and FIG. 4b may be used in a system which further comprises a second heating unit operative to provide energy to the substrate 130 from a top side thereof.

As illustrated in FIGS. 4a and 4b, the gas inlets 111 are inclined to rotate the substrate. That is, the gas inlets 111 of create a rotational effect in addition to the levitation effect explained above by the application of gas (levitation/rotation gas) to the substrates bottom surface.

Rotation speeds of 0-3000 rpm may be achieved with a gas flow of 0-10 slm providing an efficiency of 300 rpm/slm or higher at lower rotation speed. The system may in particular be adapted to rotate the substrate 130 with a rotational velocity between 60 rpm and 2000 rpm. Due to the gas flow the substrate is not only rotating, but also lifted up from the surface between 0 and 3 mm from a flat surface of the carrier 110.

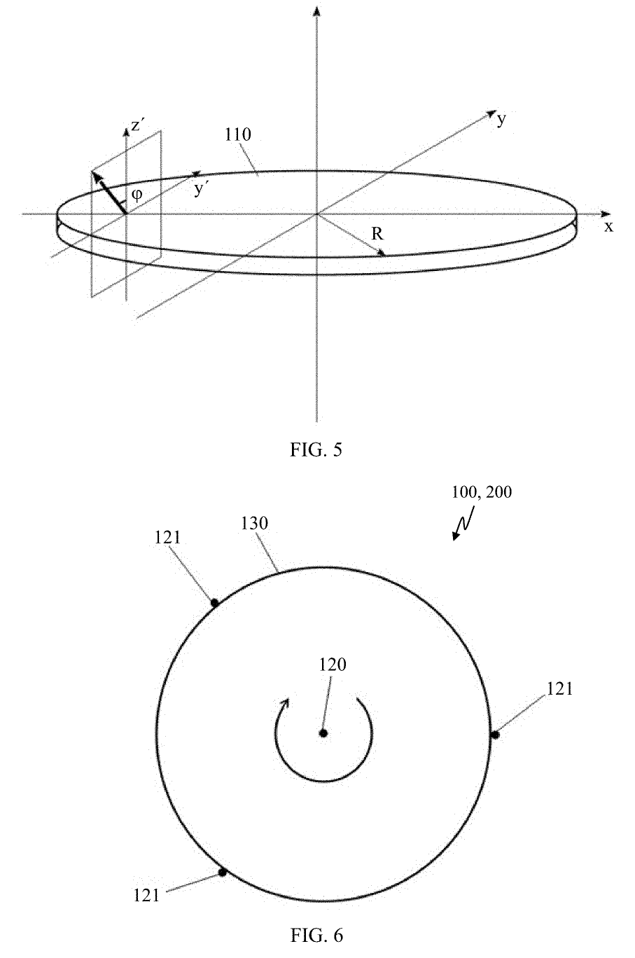

The definition of the inclination of the gas inlets with respect to the carrier may best be described with reference to FIG. 5.

FIG. 5 shows the carrier 110 and a coordinate system, wherein the z-axis is the normal direction with respect to the carrier 110. The x- and y-axis are perpendicular to the z-axis and lie within the plane of the carrier 110. The x-axis is further defined by the location of the respective gas inlet. That is, the x-axis spreads along the diameter of the carrier 110 going through the location of the gas inlet. Furthermore, the x- and y-axis are perpendicular to each other.

In addition, FIG. 5 shows a plane which is defined by a vector z′ and a vector y′, wherein z′ is parallel to the z-axis and y′ is parallel to the y-axis. The inclination of the gas inlet is then defined as the angle φ, i.e. the deviation from the z′ direction.

By the above definition, it is clear that the orientation of the y′-z′-plane depends on the location of the gas inlet. In other words, the orientation of the coordinate system depends on the location of the respective gas inlet.

Although the definition of the inclination angle φ of the gas inlets according to FIG. 5 is based on the relation of the carrier 110, the skilled person will appreciate that the same description may hold true with respect to the substrate 130. That is, the coordinate system in FIG. 5 may be defined with respect to the substrate 130 instead of the carrier 110.

The inclination angle φ may be between 2° and 60°, preferably between 5° and 50°, even more preferably between 10° and 45°. In exemplary embodiments, the inclination angle φ may be between 25° and 35° or between 28° and 32°. Particularly effective levitation and rotation of the substrate 130 can be attained using an inclination angle φ in the indicated ranges.

The gas inlets 111 may be positioned on a circular line that is concentric with the carrier 110. A distance between each of the at least three gas inlets and a center axis of the carrier may be greater than 30% of a radius of the substrate, preferably greater than 50% of the radius of the substrate, more preferably greater than 70% of the radius of the substrate. The distance between each of the at least three gas inlets and a center axis of the carrier may be greater than 50 mm, preferably greater than 65 mm, more preferably greater than 80 mm, for example.

Although the carrier 110 is illustrated in a circular shape, the carrier may have any kind of geometry. The same holds true for the substrate, which may have a circular or any other shape.

FIG. 6 illustrates the system according to an exemplary embodiment of the present invention. FIG. 6 is a top view of the system 100, 200 and shows holding members 120, 121 and a substrate 130. The system illustrated in FIG. 6 comprises both the holding member 120 provided at a center region of the substrate 130 and plural, in particular at least three, holding members 121 are provided at an edge region of the substrate 130.

Furthermore, an exemplary rotation direction of the substrate is illustrated by the arrow in FIG. 6.

The holding members 120, 121 according to FIGS. 2, 3 and 6 may have a varying diameter (not shown) such that the substrate 130 is being held at a certain distance above the carrier 110. Thus, the diameter may be larger at the bottom of the holding member 120. The diameter of the holding member 120 may increase gradually towards the carrier 110 or may be varied by a step portion at a predetermined height above the carrier.

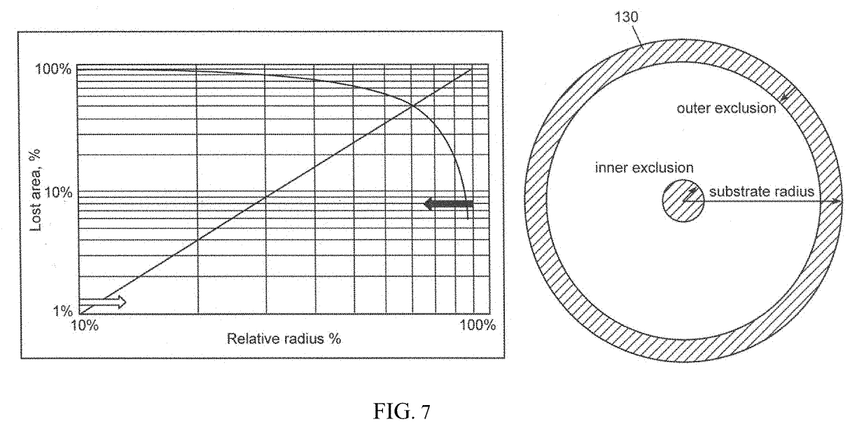

FIG. 7 illustrates the relationship between the lost area development for cutting the substrate from the center and the edge for comparison. That is, the area which is unusable after processing is illustrated depending on the use of a carrier according to the prior art (outer exclusion) or the use of a central pin (holding member 120).

As can be seen from the graph in FIG. 7, the inner 10% of the radius represent negligible 1% of the surface area of the substrate. That is, a central pin (holding member 120) causing a lost area of 10% may lead to an unusable surface area of the substrate of 1%.

In contrast, the outer 10% ring (outer exclusion) represents 20% of the surface area of the substrate. That is, the inner exclusion area may be economically more valuable (by a factor of 10-50; factor 10 @18% exclusion, factor 50 @4%) compared to the outer exclusion area.

In addition, by using three outer pins (holding members 121) the outer exclusion area may be reduced, because the lost area would be restricted to the area around the outer pins. However, using a rotational substrate, the exclusion areas may be avoided completely.

Furthermore, the inner pin creates additional possibilities for the substrate handling and position adjustment for the equipment.

The system according to any one of the embodiments may be adapted to rotate the substrate 130 with a rotational velocity between 60 rpm and 2000 rpm. A control unit of the system may be adapted to adjust a volume flow rate and/or flow velocity of the gas passed through each of the gas inlets 111 so as to attain a desired rotational velocity of the substrate 130. Closed-loop control may be used for that purpose. The actual, current rotational velocity of the substrate 130 may be sensed by a sensor coupled to the holding member(s) 120, 121 or by using a rotational sensor separate from the holding member(s) 120, 121.

Alternatively or additionally to sensing a rotational speed of the substrate 130, the system may be adapted to sense a position of the substrate 130. Position sensing may be performed using the holding member(s) 120, 121. For illustration, contact switches or other sensors may be provided on the holding member(s) 120, 121 to detect disengagement of the substrate 130 from an abutment surface on the holding member(s) 120, 121, on which the substrate 130 abuts prior to being levitated by the gas flow passing through the gas inlets 111.

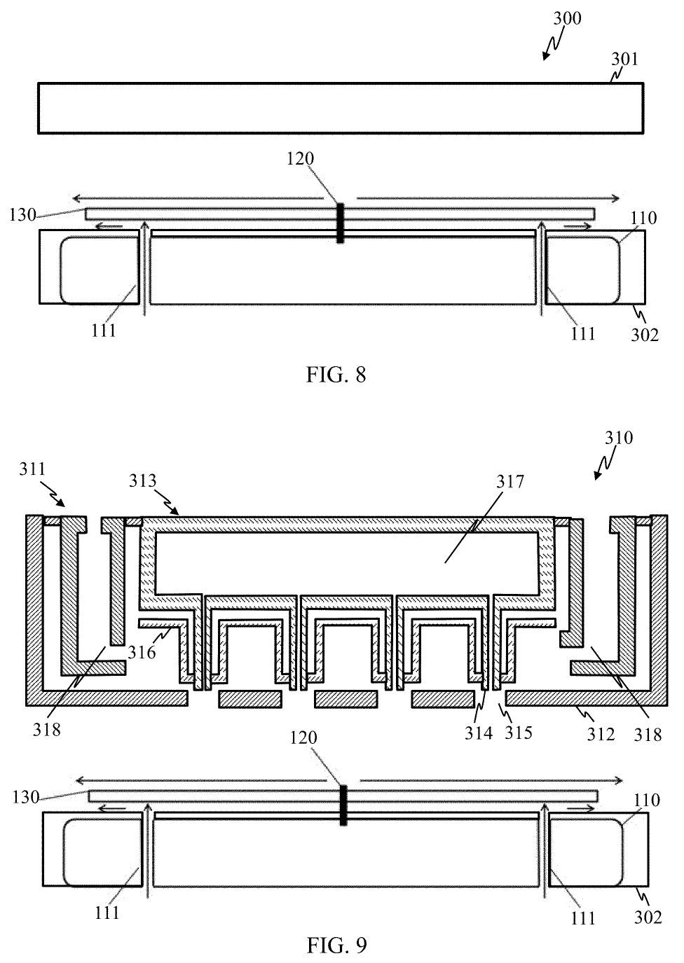

FIG. 8 is a schematic illustration of a system 300 according to an embodiment. The system 300 comprises a heater adapted to heat the substrate 130 both from a side of a top surface of the substrate 130 and from a side of the bottom surface of the substrate 130. The heater may comprise a first heating unit 302 arranged below the substrate 130 and a second heating unit 301 arranged above the substrate 130. The first heating unit 302 may act as the carrier 110 or may comprise the carrier 110 in which the at least three gas inlets 111 are formed.

By applying energy to a levitated and rotated substrate 130 from both a side of the top surface and a side of the bottom surface of the substrate 130, a better uniformity of temperature at both the top surface and the bottom surface may be attained. The risk of strain between the top and bottom surfaces of the substrate 130, which could potentially give rise to an undesired reduction in layer quality, may be reduced.

A control unit of the system 300 may be adapted to control the first heating unit 302 and the second heating unit 301 independently of each other. The first heating unit 302 and the second heating unit 301 may be controlled such that a first power output of the first heating unit 302 and second power output of the second heating unit 301 are varied as a function of time in a manner in a coordinated manner.

When the first heating unit 302 also acts as carrier 110, it is not required to provide a separate carrier 110 comprising the gas inlets 111, thus keeping installation space requirements moderate.

FIG. 9 is a schematic illustration of a system 310 according to an embodiment. The system 300 comprises a heater adapted to heat the substrate 130 both from a side of a top surface of the substrate 130 and from a side of the bottom surface of the substrate 130. The heater may comprise a first heating unit 302 arranged below the substrate 130 and a gas injection and heating unit 311 arranged above the substrate 130. The first heating unit 302 may act as the carrier 110 or may comprise the carrier 110 in which the at least three gas inlets 111 are formed.

The gas injection and heating unit 311 may comprise a heater plate 312 adapted to supply energy to the substrate 130 from the side of the top surface of the substrate 130. The gas injection and heating unit 311 may comprise a gas injector 313. The gas injector 313 may comprise gas outlets 314, which may be hollow pins, and which respectively have an internal cavity extending along a longitudinal axis of the gas outlets 314, to thereby guide the process gases towards the process area of the substrate 130. The gas outlets 314 may be aligned with orifices 315 in the heater plate 312.

The gas injector 313 may comprise a first flow path 317 and a second flow path 318. The first and second flow paths 317, 318 are arranged in such a manner that the first flow path 317 and the second flow path 318 are respectively configured to output process gases towards the substrate 10 through common orifices 315, which may be formed in the heater plate 312. The first and second flow paths 317, 318 may be arranged to face the top surface of the substrate 130.

The system 310 may allow the temperature of process gases passing through the first flow path 317 and the temperature of process gases passing through the second flow path 318 to be controlled independently of each other. For illustration, separate controllable heating and/or cooling elements may be provided for the first flow path 317 and the second flow path 318. A power output of the heater plate 312 may also be controllable to allow three temperatures to be controlled essentially independently within one process chamber, i.e., the temperature of the process gases passing through the first flow path 317, the temperature of the process gases passing through the second flow path 318, and the substrate temperature. Enhanced process control is attained thereby.

FIG. 10 shows a system 330 for gas phase deposition according to an embodiment. The system 330 may be adapted for Metalorganic Vapor Phase Epitaxy (MOVPE) or Metalorganic Chemical Vapor Deposition (MOCVD), or other gas phase deposition methods.

The system 330 is operative to deposit one or several different materials onto a substrate 130 in a process chamber 350. The process chamber 350 may be a reactor. As will be explained in more detail below, the system 330 is configured in such a manner that a first group of process gases may be passed through the first flow path of the gas injection and heating unit 311 and that a second group of process gases may be passed through the second flow path of the gas injection and heating unit 311. The first flow path and the second flow path may be arranged to face the same surface of the substrate 130, which may be one of the major surfaces of the substrate.

The system 330 may comprise a first bubbler 331 which may be connected to the process chamber 350 so as to supply a first group of process gases to the first flow path of the gas injection and heating unit 311. The system 330 may comprise a second bubbler 334 which may be connected to the process chamber 350 so as to supply a second group of process gases to the second flow path of the gas injection and heating unit 311. Ducts 332 may provide process gases to the process chamber 350. The first and second group of process gases may be different from each other. Sources of reactants or precursors different from bubblers may be used. For illustration, gas sources, vaporizers, vapour sources, or other sources of reactants or precursors may be used. As used herein, the term “process gas” is used to refer to gas which includes at least one of a reactant, a precursor, a carrier gas, or mixtures thereof. The terms “a process gas” or a group of process gas” may be used to refer to carrier gas in which reactants or precursors may be entrained, for example. A process gas may be entrained in the same carrier gas or in two or more different carrier gases. The term “group of reactants” is used to refer to the sources for physicochemical reactions with a purpose to grow different kind of layers or to etch grown layers or substrate itself. Reactants in most cases are in gaseous state, but not limited thereto. Reactants can consist 100% of substance or may be diluted to a certain extent with a gas not taking part in physicochemical reactions. The reasons for substance dilution can be different. Such reasons may include, without limitation, safety, necessity to supply only a small amount of substance in case of doping purpose to the requirements to achieve the total flow balance (to avoid turbulences or back flow regime) and to grow or etch uniform layers from the thickness and composition point of view in cross-flow or, as they are also called in a different way, horizontal flow reactors. In the two latter cases such a dilution gas is called carrier gas and has the role of bringing the group of reactants to a certain distance within the reactor area or to compensate the flow of another group of reactants to avoid turbulences or even clogging, which might work as gas-based valve preventing the certain group of reactants to reach the substrate surface. The carrier gas, if present, may include one or several of H₂, N₂, elements of group VII, or other appropriate gases.

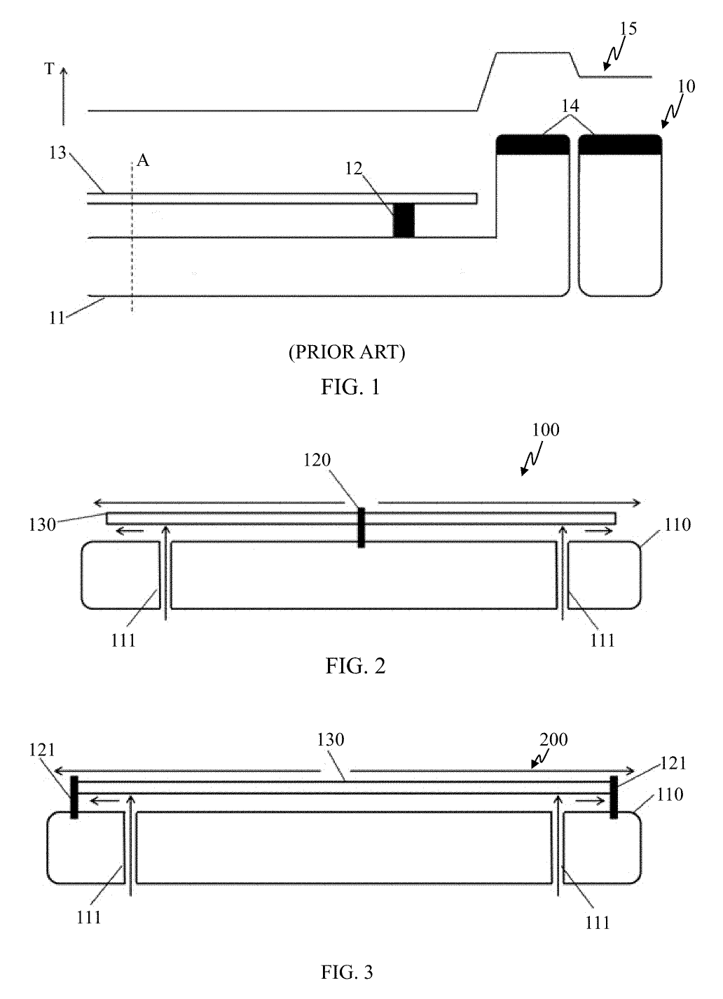

The system 330 may comprise a source 333 of gas that is passed through the gas inlets 111 in the first heating unit 302. The gas inlets 111 in the first heating unit 302 may have any one of the configurations described with reference to FIG. 1 to FIG. 9 above.

The system 330 may comprise a control unit (not shown). The control unit may comprise one or several integrated circuits, such as processors, microprocessors, application specific integrated circuits, controllers, microcontrollers, or combinations thereof that are configured to control operation of at least some components of the system 330. The system may comprise valves or other flow control components (not shown) that control the flow of the first group of process gases and of the second group of process gases to the gas injection and heating unit 311. The control unit may be configured to control the valves or other flow control components to set the flow of process gases and the flow of gas supplied to the gas inlets 111 in the first heating unit 302 for levitation and rotation of the substrate.

The system 330 may comprise temperature control mechanisms connected to the first heating unit 302 and to a second heating unit 312 that is integrated into the gas injection and heating unit 311, so as to control the amount of energy supplied to the substrate from a side of the top surface and form a side of the bottom surface of the substrate.

The substrate 130 may be held in the process chamber 350 by at least one holding member 120. The at least one holding member 120 may be adapted to hold the substrate 130 in a spaced relationship from the first heating unit 302 even before the substrate is levitated by the flow of gas through the gas inlets 111. When gas is passed through the gas inlets 111 in the first heating unit 302, levitation and rotation of the substrate 130 is effected, thereby increasing the spacing between the substrate and a top surface of the first heating unit 302 which acts as carrier.

While a carrier 110 having a single, centrally arranged holding member 120 is schematically illustrated in FIG. 8, FIG. 9, and FIG. 10, the systems 300, 310, and 330 may respectively comprise a plurality of holding members 121 arranged along an outer circumference of the substrate 130, in addition or as an alternative to a centrally arranged holding member 120.

In any one of the embodiments disclosed herein, the holding member(s) 120, 121 may be implemented in various ways. The holding member(s) 120, 121 may have a longitudinal axis extending perpendicular to the top and bottom surfaces of the substrate 130. A cross-sectional area of the holding member(s) 120, 121 may increase towards the carrier 110. The holding member(s) 120, 121 may be non-rotatably attached to the carrier 110 or may be rotatably attached to the carrier 110.

FIG. 11 is a schematic cross-sectional view of a holding member 401 that may be used in the system according to an embodiment. The holding member 401 comprises a plurality of cylindrical portions. A first cylindrical portion having a first diameter is attached to or integrally formed with a second cylindrical portion having a second diameter larger than the first diameter. The holding member 401 is attached to the carrier 110 via a mount 411. The mount 411 may attach the holding member 401 to the carrier 110 in a torque-prove manner.

During use, the substrate 130 may abut on a step surface formed at the transition between the first cylindrical portion and the second cylindrical portion before the substrate 130 is levitated. When levitation of the substrate 130 is initiated, the substrate 130 may move out of abutment with the step surface formed at the transition between the first cylindrical portion and the second cylindrical portion. The system is configured such that the substrate 130 is not lifted to a height higher than the top of the holding member 401. This ensures that the first cylindrical portion will remain positioned adjacent the substrate 130 so as to limit horizontal drifting thereof

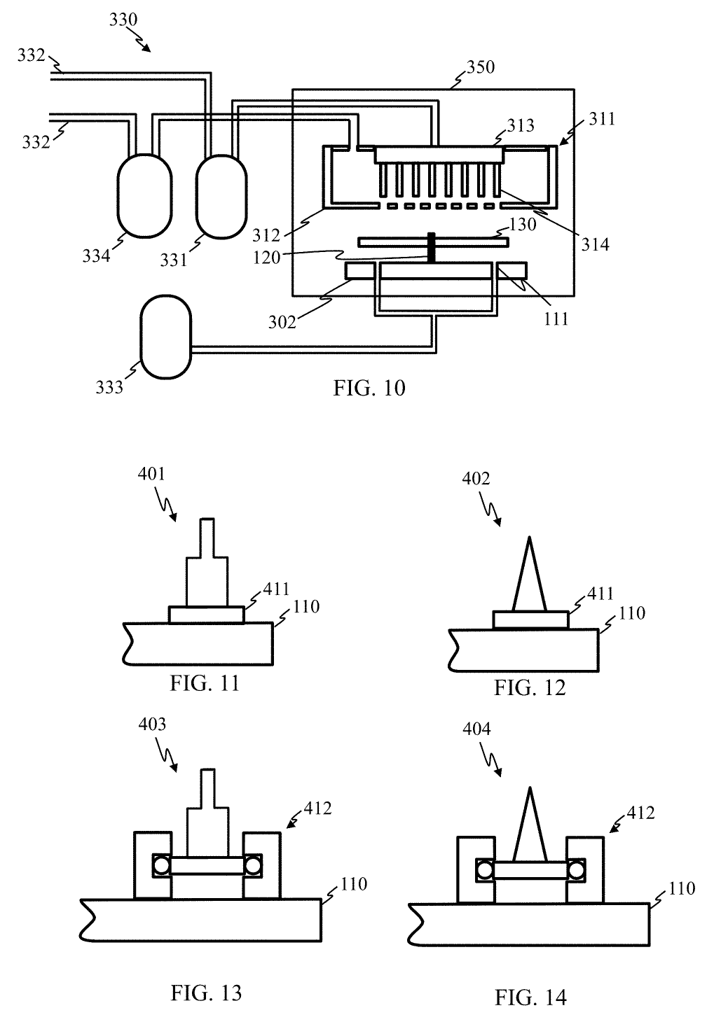

FIG. 12 is a schematic cross-sectional view of a holding member 402 that may be used in the system according to an embodiment. The holding member 402 comprises a member having a conical or frustoconical outer surface. The holding member 402 is attached to the carrier 110 via a mount 411. The mount 411 may attach the holding member 402 to the carrier 110 in a torque-prove manner.

During use, the substrate 130 may abut on the conical or frustoconical outer surface of the holding member 402. When levitation of the substrate 130 is initiated, the substrate 130 may move out of abutment with the conical or frustoconical outer surface of the holding member 402. The system is configured such that the substrate 130 is not lifted to a height higher than the top of the holding member 402. This ensures that the holding member 402 will remain positioned adjacent the substrate 130 so as to limit horizontal drifting thereof.

FIG. 13 is a schematic cross-sectional view of a holding member 403 that may be used in the system according to an embodiment. The holding member 403 comprises a plurality of cylindrical portions and has a structure and operation similar to that of the holding member 401 explained with reference to FIG. 11. However, the holding member 403 is rotatably attached to the carrier 110 via a mount 412. The mount 412 may comprise a ball bearing or roller bearing. The holding member 403 may be attached to an inner bearing ring which is rotatable relative to an outer bearing ring attached to the carrier 110. Balls or rollers may be interposed between the inner and outer bearing rings. The holding member 403 may be rotated as the substrate 130 is caused to rotate under the influence of the gas flow passing through the inlets 111.

FIG. 14 is a schematic cross-sectional view of a holding member 404 that may be used in the system according to an embodiment. The holding member 404 comprises a member having a conical or frustoconical outer surface and has a structure and operation similar to that of the holding member 402 explained with reference to FIG. 12. However, the holding member 404 is rotatably attached to the carrier 110 via a mount 412. The mount 412 may comprise a ball bearing or roller bearing. The holding member 404 may be attached to an inner bearing ring which is rotatable relative to an outer bearing ring attached to the carrier 110. The holding member 404 may be rotated as the substrate 130 is caused to rotate under the influence of the gas flow passing through the inlets 111.

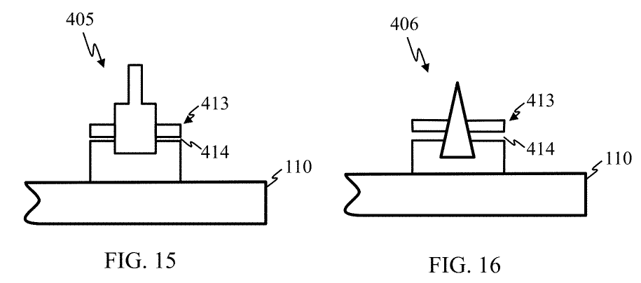

FIG. 15 is a schematic cross-sectional view of a holding member 405 that may be used in the system according to an embodiment. The holding member 405 comprises a plurality of cylindrical portions and has a structure and operation similar to that of the holding member 401 explained with reference to FIG. 11. However, the holding member 405 is rotatably attached to the carrier 110 via a mount 413. The mount 413 may comprise a gas bearing. Gas passages 414 may be formed in the gas bearing to rotatably support the holding member 405 when gas is passed through the gas passages 414. The gas passages 414 may be in fluid communication with a gas supply that supplies gas to the gas inlets 111 in the carrier 110. The holding member 405 may be rotated as the substrate 130 is caused to rotate under the influence of the gas flow passing through the gas inlets 111.

FIG. 16 is a schematic cross-sectional view of a holding member 406 that may be used in the system according to an embodiment. The holding member 406 comprises a member having a conical or frustoconical outer surface and has a structure and operation similar to that of the holding member 402 explained with reference to FIG. 12. However, the holding member 406 is rotatably attached to the carrier 110 via a mount 413. The mount 413 may comprise a gas bearing. Gas passages 414 may be formed in the gas bearing to rotatably support the holding member 406 when gas is passed through the gas passages 414. The gas passages 414 may be in fluid connection with a supply that also supplies gas to the gas inlets 111 in the carrier 110. The holding member 406 may be rotated as the substrate 130 is caused to rotate under the influence of the gas flow passing through the gas inlets 111.

While holding members 403, 404, 405, and 406 rotatably supported on the carrier 110 by a ball bearing, roller bearing, or gas bearing have been explained with reference to FIG. 13 to FIG. 16, other attachment mechanisms that allow the holding member to rotate relative to the carrier 110 may also be used. When the holding member is rotatably mounted to the carrier 110, the holding member may be caused to rotate when the substrate rotates. The holding member may be actively driven, e.g., by a gas flow, to rotate in a manner which reduces or even eliminates slip between the holding member and the part of the substrate 130 closest to the holding member.

The implementations of the holding members explained in detail above may be used both in systems that comprise a single holding member to restrict horizontal drifting of the substrate and in systems that comprise plural holding members to restrict horizontal drifting of the substrate.

In any one of the embodiments disclosed herein, the holding member(s) may be operative to hold the substrate 130 at a predetermined first distance from the carrier 110 even before levitation is induced by a gas flow through the gas inlets 111 in the carrier 110. The gas flow through the gas inlets 111 may cause the distance between the bottom surface of the substrate 130 and the top surface of the carrier 110 to increase to a second distance greater than the first distance. The substrate 130 may thus be kept at a distance from the carrier 110 in any operational state.

The surface of the carrier 110 facing the substrate 130, i.e., the top surface of the carrier 110, does not need to be provided with any recesses. The top surface of the carrier 110 may be substantially flat. The top surface of the carrier 110 may have a surface flatness of at most 0.1 mm.

As the present invention may be embodied in several forms without departing from the scope or essential characteristics thereof, it should be understood that the above-described embodiments are not limited by any of the details of the foregoing descriptions, unless otherwise specified, but rather should be construed broadly within the scope as defined in the appended claims, and therefore all changes and modifications that fall within the present invention are therefore intended to be embraced by the appended claims.

Furthermore, in the claims the word “comprising” does not exclude other elements or steps, and the indefinite article “a” or “an” does not exclude a plurality. A single unit may fulfil the functions of several features recited in the claims. The terms “essentially”, “about”, “approximately” and the like in connection with an attribute or a value particularly also define exactly the attribute or exactly the value, respectively. The words carrier, holder, satellite, plate, platter, susceptor etc. represent the same meaning in this text and are in use interchangeably. The same is valid for the group of words like channel, hollow tube, hole, path etc. The variety of definitions has a regional and/or a professional origin.

What is claimed is:

1. System for simultaneous rotation and levitation of a substrate during deposition and/or etching of the substrate, the substrate having a bottom surface and a top surface, wherein the system comprises:
a heater configured to apply heat to the bottom surface of the substrate and to the top surface of the substrate, the heater comprising a carrier located below the substrate, wherein the carrier comprises at least three gas inlets to provide gas to the substrate's bottom surface to levitate the substrate above the carrier and to simultaneously rotate the substrate; and
at least one holding member connected to the carrier and being configured to restrict horizontal drifting of the substrate.

2. System according to claim 1, wherein the gas inlets are inclined with respect to a vector normal to the bottom surface of the substrate, wherein an inclination angle (φ) of the inclined gas inlets is between 2° and 60°.

3. System according to claim 1, wherein the at least one holding member comprises a single holding member located at the carrier such that the holding member engages with the substrate at a central position thereof or wherein the at least one holding member comprises at least three holding members located at the carrier such that the three holding members confine horizontal movement of the substrate at an edge region thereof.

4. System according to claim 1, wherein the at least one holding member comprises a pin, which preferably has an increasing diameter towards the carrier.

5. System according to claim 1, wherein the upper surface of the carrier facing the substrate has a surface flatness of at most 0.1 mm.

6. System according to claim 1, wherein the at least three gas inlets are formed as a hole or a hollow pin through the carrier.

7. System according to claim 1, wherein a distance between each of the at least three gas inlets from a center of the carrier is greater than 30% of a radius of the substrate.

8. System according to claim 1, wherein the at least one holding member further comprises a rotational speed sensor and/or a positional sensor to measure the rotation and/or the position of the substrate.

9. System according to claim 1, wherein the heater comprises a first heating unit provided below the bottom surface of the substrate and a second heating unit provided above the top surface of the substrate, wherein the first heating unit comprises the carrier.

10. System according to claim 1, wherein the system is adapted to rotate the substrate with a rotational velocity between 60 rpm and 2000 rpm.

11. System according to claim 1, wherein the system is adapted to control the gas flow through the at least three gas inlets in order to control the rotational velocity of the substrate.

12. Method for simultaneous rotation and levitation of a substrate during deposition and/or etching of the substrate, the substrate having a bottom surface and a top surface, the method comprising the steps of:
(a) applying gas to the bottom surface of the substrate which faces a carrier through at least three gas inlets formed in the carrier to levitate the substrate above the carrier and to simultaneously rotate the substrate;
(b) restricting horizontal drifting of the substrate during levitation by means of at least one holding member; and
(c) heating the bottom surface and the top surface of the substrate during levitation and rotation.

13. Method according to claim 12, wherein applying gas through the at least three gas inlets comprises applying gas under a predetermined inclination angle defined by a deviation from a vector normal to the bottom surface of the substrate, wherein the inclination angle is between 2° and 60°.

14. Method according to claim 12, wherein restricting horizontal drifting is achieved by engagement of a single holding member with an opening provided at a centre of the substrate or by confining the substrate's edge with at least three holding members positioned along an edge of the substrate.

15. Method according to claim 12, further comprising applying a process gas to the top surface of the substrate for the purpose of deposition and/or etching during levitation and rotation.

16. Method according to claim 15, further comprising holding the substrate at a predetermined first distance from the carrier before the application of the gas and at a predetermined second distance from the carrier after application of the gas by means of the least one holding member, wherein the predetermined second distance is greater than the predetermined first distance.

17. Method according to claim 12, wherein a distance between each of the at least three gas inlets from a center of the carrier is greater than 30% of a radius of the substrate.

18. Method according to claim 12, further comprising measuring the rotation and/or the position of the substrate.

19. Method according to claim 12, wherein the bottom surface and the top surface of the substrate are heated independently from each other.

20. Method according to claim 12, wherein the substrate is rotated with a rotational velocity between 60 rpm and 2000 rpm.

21. Method according to claim 12, further comprising the step of controlling the gas flow through the at least three gas inlets in order to control the rotational velocity of the substrate.

22. The system of claim 1 for vapor phase deposition.

23. The method of claim 12 for vapor phase deposition.
